(19) United States
(12) Patent Application Publication
(10) Pub. No.: US 2011/0278657 A1
(43) Pub. Date: Nov. 17, 2011

(54) APPARATUS, SYSTEM, AND METHOD FOR CAPACITANCE CHANGE NON-VOLATILE MEMORY DEVICE

(76) Inventors: Kwan-Yong Lim, Seongnam-Si (KR); Chanro Park, Austin, TX (US); Hokyung Park, Latham, NY (US); Paul Kirsch, Austin, TX (US)

(21) Appl. No.: 12/777,866

(22) Filed: May 11, 2010

(51) Int. Cl. H01L 29/788; H01L 21/326; H01L 21/336

(52) U.S. Cl. 257/316; 438/264; 438/466; 257/E29.3; 257/E21.422; 257/E21.327

(57) ABSTRACT

An apparatus, system, and method for a capacitance change non-volatile memory device. The apparatus may include a substrate, a source region in the substrate, a drain region in the substrate, a tunnel oxide layer on the substrate substantially between the source region and the drain region, a floating gate layer on the tunnel oxide layer, a resistance changing material layer on the floating gate layer, and a control gate on the resistance changing material layer.

### BACKGROUND OF THE INVENTION

1. Field of the Invention

This invention relates to non-volatile memory device, and more particularly relates to an apparatus, system, and method for a capacitance change non-volatile memory device.

2. Description of the Related Art

Computers may use two types of memory, which are sometimes referred to primary and secondary storage. Primary storage tends to be used for fast execution of instructions or temporary storage of data. Primary storage is typically implemented as volatile random access memory (RAM). The term volatile refers to the characteristic that the contents of the memory are lost when power is removed from the memory.

Secondary storage is typically used for long-term storage and tends to hold large amounts of data. To serve as long term storage, secondary storage devices tend to be non-volatile, meaning that the contents of the device remain even if the power to the device is removed. Some examples of secondary storage include hard disk drives and flash based devices such as a USB flash drive.

Recent developments in technology have increased the demand for small, low-power non-volatile memories. For example, portable music players and digital cameras have increased the demand for flash-based memory for storing music and pictures. With the increased need for capacity, manufacturers have continued to increase the density of non-volatile memory to provide more storage capacity in smaller packages.

Flash-based memories may use a floating gate transistor for storing bits. FIG. 1 shows an example of a floating gate transistor 100. The transistor 100 includes a substrate 102, a source 104, and a drain 106. The floating gate 110 is separated from the substrate 102 by an oxide layer 108. Above the floating gate 110 is the control gate 112.

The floating gate 110 is a piece of metal or polycrystalline silicon that is completely surrounded by an insulator. Electrons are stored in the floating gate 110 and the surrounding insulator prevents the electrons from escaping. The presence or lack of electrons in the floating gate 110 determine the memory state of each transistor. Although widely used, the floating gate transistor has some disadvantages. First, because the memory state is determined by stored electrons, leakage of electrons may cause the memory device to lose its memory. Because it is important to prevent the leakage of electrons, the insulator surrounding the floating gate cannot be too thin. For example, the insulator between a gate and the substrate in a typical device is about 200 Angstroms. A thin insulator will increase the probability of electrons escaping and the memory state of a device may be lost. A lower limit on the size of the insulator limits how small a floating gate transistor may be and, consequently, places an upper limit on memory density. Another disadvantage of a large insulator around the floating gate is wear. The insulator “wears” after repeated read and write cycles, which limits the useful life of a floating gate transistor. A typical floating gate transistor is guaranteed to last 100,000 writes. Additionally, the thicker the insulator, the more degradation that occurs during each write cycle.

### SUMMARY OF THE INVENTION

An apparatus for non-volatile memory is presented. In one embodiment, the apparatus includes a substrate, a source region in the substrate, a drain region in the substrate, a tunnel oxide layer on the substrate substantially between the source region and the drain region, a floating gate layer on the tunnel oxide layer, and a resistance changing material layer on the floating gate layer. In some embodiments, the resistance changing material layer comprises a resistance changing material. In some embodiments, the apparatus includes a control gate on the resistance changing material layer.

In some embodiments, the substrate may be silicon (Si), germanium (Ge), a compound of Si and Ge (SiGe) or a compund of class III and V elements. In some embodiments, the substrate may be implanted with a p-type dopant, such as boron (B). In some embodiments, the source region and the drain region may be implanted with an n-type dopant such as arsenic.

In some embodiments, the tunnel oxide layer on the substrate may be made of high-K dielectrics, silicon oxide, hafnium silicon oxynitride (HfSiON), or other oxides. In some embodiments, the tunnel oxide layer may be located substantially between the source region and the drain region. In some embodiments, the tunnel oxide layer may slightly overlap the source region and/or the drain region.

In some embodiments, the tunnel oxide layer is less than about 30 Angstroms thick. The tunnel oxide layer may be thin to maximize direct tunneling behavior. The tunnel oxide layer may also be thin to minimize degradation of the oxide layer.

In some embodiments, the floating gate layer may be made of polycrystalline Si, polycrystalline SiGe, titanium nitride (TiN), tungsten (W), tungsten nitride (WN), molybdenum (Mo), molybdenum nitride (MoN), tantalum (Ta), tantalum nitride (TaN), cobalt (Co), cobalt nitride (CoN), titanium silicon nitride (TiSiN), tantalum silicon nitride (TaSiN), tungsten silicon nitride (WSiN), Nickel (Ni), nickel silicide (NiSi), cobalt silicide (CoSi), platinum silicide (PtSi), tungsten silicide (WSi), titanium silicide (TiSi), copper (Cu), or platinum (Pt).

In some embodiments, the resistance changing material layer may be made of a resistance changing material such as titanium oxide (TiOx), nickel oxide (NiOx), copper oxide (CuOx), tungsten oxide (WOx), molybdenum oxide (MOx), aluminum oxide (AlOx), cobalt oxide (CoOx), iron oxide (FeOx), hafnium oxide (HfOx), tantalum oxide (TaOx), zirconium oxide (ZrOx), gadolinium oxide (GdOx), germanium oxide (GeOx), silicon oxide (SiOx) or a composit of two or more different metal oxide films.

In some embodiments, the resistance changing material layer is configured to alternate between a low resistance state and a high resistance state. The resistance changing material may be a dielectric. A filament, or a low resistance path, may be formed in the resistance changing material after a sufficiently high voltage is applied to the resistance changing material. The forming of the filament may be referred to as “setting” the resistance changing material. The formation of the filament may be formed through different mechanisms, such as defects or metal migration. The filament may then be eliminated by applying a sufficiently high voltage. In some embodiments, the heat from the applied current causes the filament to disappear and the resistance changing material goes back to being a dielectric with high resistance. In some embodiments, the act of eliminating the filament is referred to as “resetting” the resistance changing material.

The resistance state of the resistance changing material may affect the effective dielectric thickness between the substrate and the control gate by alternating between a high resistive state and a low resistive state.

In some embodiments, the effective dielectric thickness between the substrate and the control gate determines the memory state of the apparatus. The effective dielectric thickness may include the combined dielectric thickness of the tunnel oxide layer and the resistance changing material layer. The effective dielectric thickness may affect the threshold voltage of the apparatus which may then determine the stored memory state.

In some embodiments, the resistance changing material layer may increase the effective dielectric thickness between the substrate and the control gate when the resistance changing material is in a high resistive state. When the resistance changing material layer increases the effective dielectric thickness, it may decrease the capacitance of the gate structure. The decreased capacitance of the gate structure may then increase the threshold voltage of the device. The increased threshold voltage may then be used to detect the memory state of the device.

In some embodiments, the resistance changing material layer may decrease the effective dielectric thickness between the substrate and the control gate when the resistance changing material is in a low resistive state. When the resistance changing material layer decreases the effective dielectric thickness, it may increase the capacitance of the gate structure. The increased capacitance of the gate structure may then decrease the threshold voltage of the device. The decreased threshold voltage may then be used to detect the memory state of the device.

An Integrated Circuit (IC) device is also presented. In some embodiments, the IC device includes a chip package configured to house an IC, a plurality of electrical interface pins coupled to the chip package and in communication with the IC, the electrical interface pins configured to conduct electrical signals, and an IC comprising at least one memory device disposed within the chip package. In some embodiments, the memory device includes a substrate, a source region in the substrate, a drain region in the substrate, a tunnel oxide layer on the substrate substantially between the source region and the drain region, a floating gate layer on the tunnel oxide layer, a resistance changing material layer on the floating gate layer, wherein the resistance changing layer comprises a resistance changing material, and a control gate on the resistance changing material layer.

In some embodiments, the resistance of the resistance changing material layer of at least one memory device determines the memory state of the memory device.

A method for fabricating a transistor is also presented. In some embodiments, the method includes providing a substrate, forming a source region in the substrate, forming a drain region in the substrate, forming a tunnel oxide layer on the substrate substantially between the source region and the drain region, forming a floating gate layer on the tunnel oxide layer, forming a resistance changing material layer on the floating gate layer, and forming a control gate on the resistance changing material layer.

In some embodiments, forming the tunnel oxide layer on the substrate substantially between the source region and the drain region may include depositing less than 30 A of silicon oxide on the substrate. For example, thermal oxidation or plasma oxidation may be used to deposit the oxide layer.

In some embodiments, forming the floating gate layer comprises depositing between ??? Angstroms of polycrystalline silicon. In some embodiments, forming the resistance changing material layer on the tunnel oxide comprises depositing between ???A of a resistance changing material.

In some embodiments, forming the resistance changing material layer comprises depositing two or more resistance changing materials.

A method for storing a memory state in a memory device is also presented. In one embodiment, the method includes applying a voltage across a control gate and a substrate, changing a resistance of a resistance changing material layer in response to the voltage, modifying an effective dielectric thickness between the substrate and the gate in response to the resistance of the resistance changing material layer, modifying a capacitance of the gate structure in response to the effective dielectric thickness, and removing the voltage without changing the resistance to substantially the value before applying the voltage.

In some embodiments, it is the binary nature of the resistance changing material that determines the memory state of the memory device. The resistance of the resistance changing material may be able to be changed and that change may remain relatively static until it is purposefully changed again. In some embodiments, the change in resistance may be sufficient to be detected by detecting a change in the threshold voltage of the device. In some embodiments, the resistance changing material may have more than two resistance states. For example, a resistance changing material may have four different resistance states and one transistor may hold two bits of stored data.

In some embodiments, changing the resistance of the resistance changing material layer in response to the voltage comprises increasing the resistance. In other embodiments, changing the resistance of a resistance changing material layer in response to the voltage comprises decreasing the resistance.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1 is a schematic block diagram illustrating one embodiment of a floating gate transistor found in the prior art.

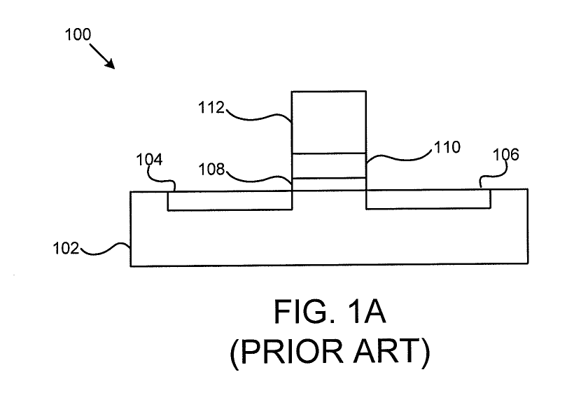

FIG. 2 is a schematic block diagram of one embodiment of a memory device.

FIG. 3 is a schematic block diagram of one embodiment of an Integrated Circuit (IC) device.

FIG. 4 is a flow chart of one embodiment for a method of fabricating a memory device.

FIGS. 5A-5F are schematic block diagrams of one embodiment of a memory device in different stages of fabrication.

FIGS. 6A-6D show energy band diagrams for memory devices as they are set and reset.

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

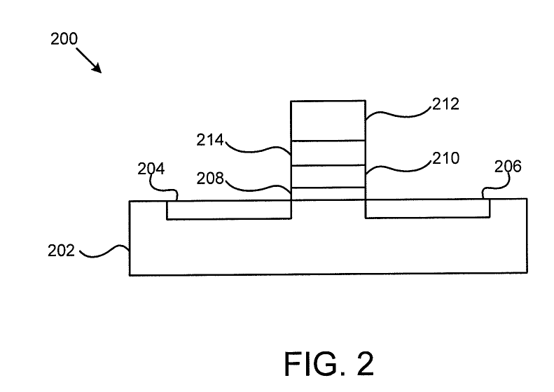

FIG. 2 illustrates one embodiment of a non-volatile memory device 200. In one embodiment, the memory device 200 includes a substrate 202. The substrate 202 may be silicon, germanium, a compound of silicon and germanium or a compound of class II and IV elements. The memory device 200 also includes a source region 204 in the substrate 202. The source region 204 may be a region of the substrate 202 that was implanted with a dopant. For example, the source region 204 may be implanted with an n-type dopant such as arsenic. The memory device 200 may also include a drain region 206 in the substrate 202. Like the source region 204, the drain region 206 may be a region of the substrate 202 that was implanted with a dopant. For example, the drain region 206 may be implanted with an n-type dopant such as arsenic.

A tunnel oxide layer 208 may be formed on the substrate 202 substantially between the source region 204 and the drain region 206. The tunnel oxide layer 208 may be less than about 30 Angstroms thick. In some embodiments, a thin tunnel oxide layer 208 may be used because the memory state may not be stored in the floating gate layer 210. One advantage of using a having a thin tunnel oxide layer 208 is that it reduces tunnel oxide degradation by being thin. Also, a thin tunnel oxide layer 208 may improve the tunneling effect of carries (e.g. holes and electrons). Another advantage of not storing the memory state of the device in the floating gate layer 210 may be that transistor size may be reduced, and memory density of integrated circuits containing memory device 200 may be increased.

A floating gate layer 210 may be formed on the tunnel oxide layer 208. The floating gate layer 210 may be made of polycrystalline Si, polycrystalline SiGe, titanium nitride (TiN), tungsten (W), tungsten nitride (WN), molybdenum (Mo), molybdenum nitride (MoN), tantalum (Ta), tantalum nitride (TaN), cobalt (Co), cobalt nitride (CoN), titanium silicon nitride (TiSiN), tantalum silicon nitride (TaSiN), tungsten silicon nitride (WSiN), Nickel (Ni), nickel silicide (NiSi), cobalt silicide (CoSi), platinum silicide (PtSi), tungsten silicide (WSi), titanium silicide (TiSi), copper (Cu), or platinum (Pt) polycrystalline silicon and may be about 5-50 nm thick. In some embodiments, the function of the floating gate layer 210 differs from the function of a floating gate in a floating gate MOSFET. For example, in a traditional floating gate MOSFET, the floating gate may serve to store the memory state of the device. In some of the present embodiments, however, the memory state is stored in a resistance changing material layer 214.

A resistance changing material layer 214 may be formed on the floating gate layer 210. In some embodiments, the resistance changing material layer 214 may include a resistance changing material. Resistance changing materials may include those that are used in ReRAM devices. For example, the resistance changing material may include, but is not limited to, one of the following materials: titanium oxide (TiOx), nickel oxide (NiOx), copper oxide (CuOx), tungsten oxide (WOx), molybdenum oxide (MOx), aluminum oxide (AlOx), cobalt oxide (CoOx), iron oxide (FeOx), hafnium oxide (HfOx), tantalum oxide (TaOx), zirconium oxide (ZrOx), gadolinium oxide (GdOx), germanium oxide (GeOx), silicon oxide (SiOx) or a composite of two or more different metal oxide films. In some embodiments, the resistance changing material layer 214 will alternate between two states: a high resistive state, and a low resistive state.

In some embodiments, the resistance changing material layer 214 is configured to alternate between a low resistance state and a high resistance state. The resistance changing material of the resistance changing material layer 214 may be a dielectric. A filament, or a low resistance path, may be formed in the resistance changing material layer 214 after a sufficiently high voltage is applied to the resistance changing material. The forming of the filament may be referred to as “setting” the resistance changing material. The formation of the filament may be formed through different mechanisms, such as defects or metal migration. The filament may then be eliminated by applying a sufficiently high voltage. In some embodiments, the heat from the applied current causes the filament to disappear and the resistance changing material goes back to being a dielectric with high resistance. In some embodiments, the act of eliminating the filament is referred to as “resetting” the resistance changing material.

A control gate 212 may be formed on the resistance changing material layer 214. The control gate 212 may have a function similar to that of a control gate in a floating gate MOSFET. The memory state of the memory device 200 may be determined by applying a voltage at the control gate 212 and sensing whether the voltage applied is above or below the threshold voltage of the device 200.

The resistive state of the resistance changing material layer 214 may affect the effective dielectric thickness between the substrate 202 and the control gate 212. For example, when the resistance changing material layer 214 is in a low resistance state, the effective dielectric thickness between the substrate 202 and control gate 212 decreases. The resistance changing material layer 214 may act as a conductor that electrically couples the control gate 212 and the floating gate 210. Therefore, the effective dielectric thickness of the control gate 212 may be primarily due to the dielectric thickness of the tunneling oxide layer 208. Conversely, when the resistance changing material layer 214 is in a high resistive state, the effective dielectric thickness between the substrate 202 and the control gate 212 may increase. For example, when the resistance changing material layer 214 is in a high resistance state, the resistance changing material layer 214 may act as an insulator, electrically separating the control gate 212 and the floating gate 210. Therefore, the effective dielectric thickness may include the dielectric thickness of the resistance changing material layer 214 as well as the dielectric thickness of the tunneling oxide layer 208.

The effective dielectric thickness between the substrate 202 and the control gate 212 may affect the capacitance of the gate structure. For example, when the resistance changing material layer 214 is in a low resistance state and the effective dielectric thickness is decreased, the capacitance of the gate structure may increase because capacitance varies inversely with dielectric thickness. Conversely, when the resistance changing material 214 is in a low resistance state and the effective dielectric thickness is increased, the capacitance of the gate structure may decrease.

A change in the capacitance of the gate structure may affect the threshold voltage of memory device 200. The threshold voltage is the voltage applied to the gate that causes tunneling to occur and current to flow between the source 204 and the drain 206. When memory device has an increased capacitance, the threshold voltage may decrease—it will take less voltage applied to the control gate 212 to cause current to flow between the source 204 and the drain 206. Conversely, when the memory device 200 has a decreased capacitance, the threshold voltage will increase.

Non-volatile memory devices that use floating gate MOSFETs, such FLASH memory, detect the memory state of an individual floating gate MOSFET by detecting a change in the threshold voltage. Therefore, one advantage of memory device 200 is that the same or similar circuitry that is used for floating gate MOSFET memory may be used to implement memory device 200 as non-volatile memory.

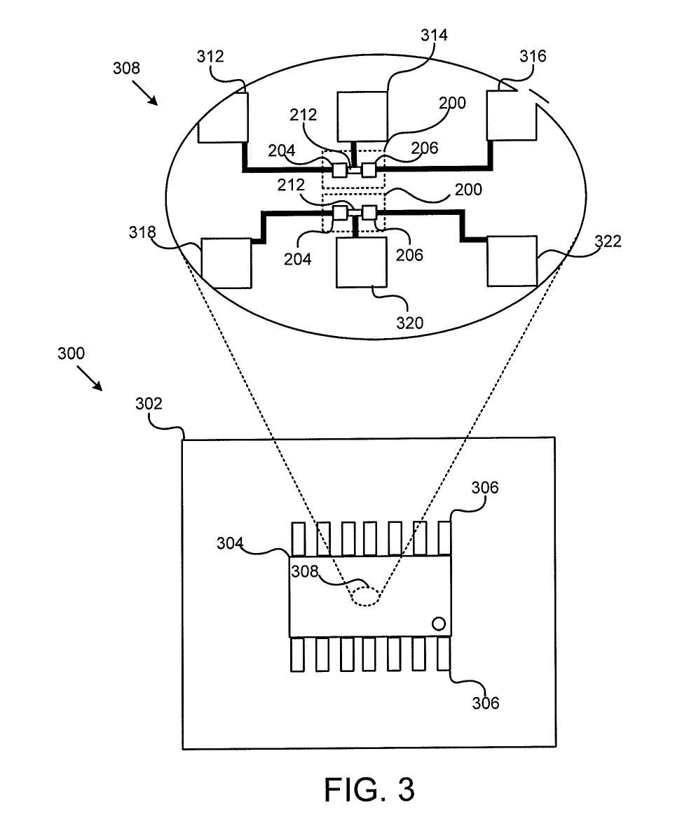

FIG. 3 shows one embodiment of an Integrated Circuit (IC) device 300. The IC device 300 includes a chip package 304 configured to house an IC 308. The chip package 304 has a plurality of electrical interface pins 306, which are coupled and in communication with the IC 308. The pins 306 are how the IC 308 is coupled to circuitry outside the chip package 304. The pins 306 are typically made of metal that is easily solderable, such as nickel or copper. The IC 308 includes at least one memory device 200. Memory device 200 may include a source region 204, a control gate 212, and a drain region 206. Refer to FIG. 2 for more information regarding memory device 200. The memory device 200 may be connected to other circuitry and/or package pins 306, shown as blocks 312, 314, and 316. The IC of FIG. 3 includes a second memory device 200 that his connected to other circuitry and/or package pints 318, 320, and 322. The memory state of memory device 200 in FIG. 3 may be determined by the resistance state of resistance changing material layer (not shown) and may be detected by circuitry 312, 314, and/or 316.

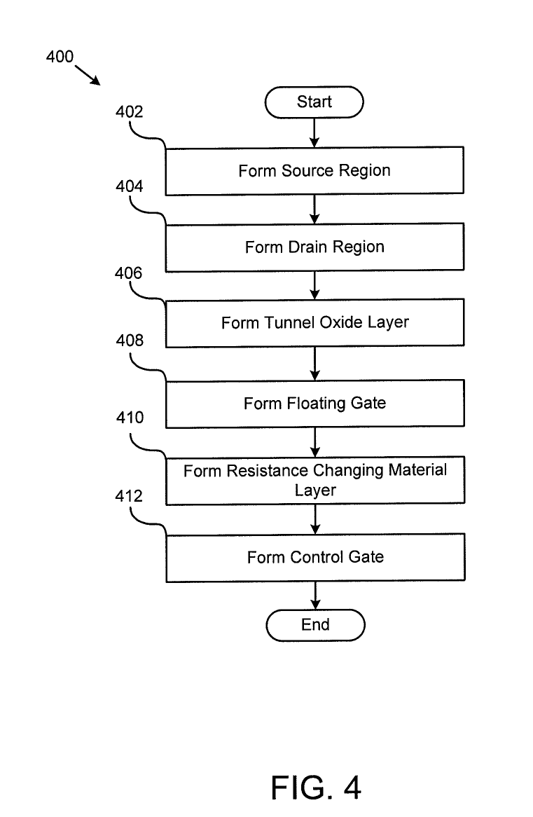

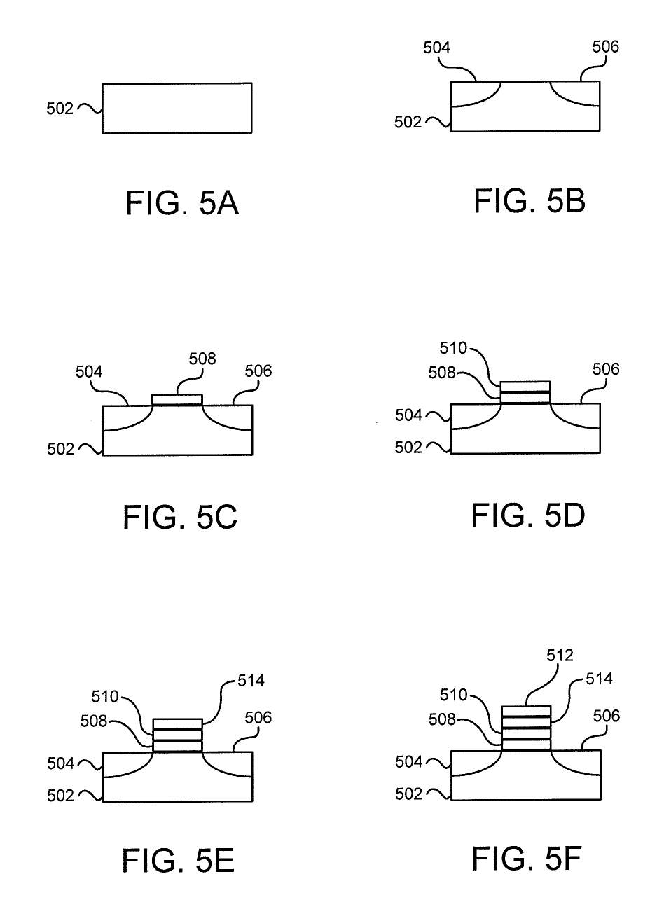

FIG. 4 shows a flow chart 400, which includes steps that may be used to fabricate a memory device 200. FIGS. 5A-5F show cross sectional views of a memory device fabricated according to flow chart 400 of FIG. 4.

Flow chart 400 begins at block 402, which describes forming a source region on a substrate. FIG. 5A shows a substrate 502 without any doped regions. FIG. 5B shows the substrate 502 with a source region 504. Doping may be accomplished using diffusion and/or ion implantation together with photolithography. For example, the source region 504 may be formed by implanting arsenic ions into the substrate 502. Block 404 shows the step of forming a drain region 506 in the substrate 502. The drain region 506 may be formed using the same or similar process as the process used to form the source region 504. Forming the drain region 506 may also be formed by diffusing or implanting a dopant, such as arsenic or boron.

Block 406 shows the step of forming the tunnel oxide layer 508 onto the substrate 502. As shown in FIG. 5C, the tunnel oxide layer 508 is located substantially between the source region 504 and the drain region 506. The tunnel oxide layer 508 may be formed, for example, using a physical vapor deposition (PVD). The tunnel oxide layer 508 may be silicon oxide (SiO₂) and may be less than about 30 Angstroms thick.

Block 408 shows the step of forming a floating gate 510 on the tunnel oxide layer 508. The floating gate 510 may be formed using, for example, PVD, and may be made of metal or polycrystalline silicon. The floating gate 510 may be about 5-50 nm thick.

Block 410 shows the step of forming the resistance changing material layer 514 on the floating gate 510. The resistance changing material layer 514 may be formed using PVD or chemical vapor deposition (CVD). The resistance changing material layer 514 may be made of, for example, titanium oxide (TiOx). In another embodiment, the resistance changing material layer 514 may be made of NiOx, CuOx, WOx, MoOx, AlOx, CoOx, FeOx, HfOx, TaOx, ZrOx, GdOx, GeOx, SiOx. In some embodiments, the step of forming a resistance changing material layer 514 may include depositing two or more types of resistance changing material. For example, the combinations of TiOx/TaOx, NiOx/TaOx, NiOx/TiOx, TiOx/NiOx/TiOx, and NiOx/TiOx/NiOx may be used. The resistance changing material layer 514 may be about 3-30 nm thick.

Block 412 shows the step of forming the control gate 512 on the resistance changing material layer 514. The control gate may be formed using PVD or CVD. The control gate 512 may be made of, for example, polycrystalline silicon.

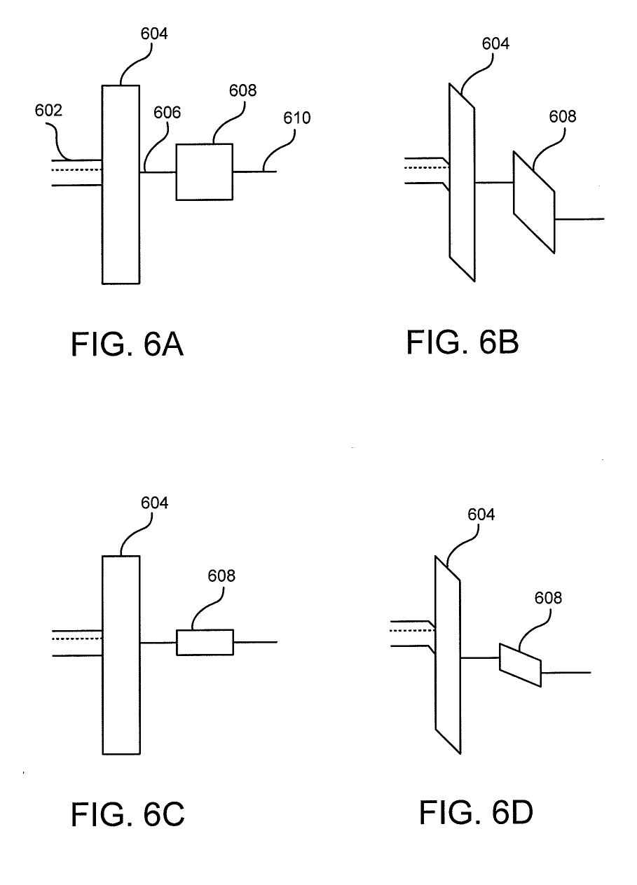

FIGS. 6A-6B show the energy diagrams of a memory device 200 as it is being set and reset. The method of setting and resetting the device may write a digital one or zero to the memory device 200. Referring to FIG. 6A and FIG. 2, the energy band of substrate 202 is shown by substrate band 602. The tunnel oxide layer 208 is represented by dielectric band 604, and the floating gate energy band is represented by floating gate band 606. The resistance changing material layer 214 is represented by RCM band 608. In FIG. 6A, the RCM band 608 is in a high resistance state and is depicted by a thick block (compared to the think block of FIG. 6C). The energy band of the control gate 212 is represented by control gate band 610.

FIG. 6B shows the memory device 200 being set when a high bias voltage is applied across the control gate 212 and the substrate 202. The shifted bands 604 and 608 represent the application of a sufficiently high voltage that causes current to flow from the substrate 202 to the control gate 212. This bias voltage may create sufficient current to change the resistance of the resistance changing material of the resistance changing material layer 214 by forming a filament (or filaments) across the resistance changing material layer 214. After the resistance changing material layer 214 has formed a filament, it may be in a low resistive state as shown in FIG. 6C. Note that band 608 in FIG. 6C is thinner than the band 608 in FIG. 6A. The thinner band represents the resistance changing material layer 214 in a low resistance state.

FIG. 6C shows how a memory device 200 being reset. A voltage may be applied between the control gate 212 and the substrate 202. Bands 604 and 608 are shown to be slanted because a sufficiently high voltage is applied to cause current to flow through the device. Because the resistance changing material layer 214 is in a low resistive state, high current can flow through the resistance changing material layer 214. High current through the resistance changing material layer 214 may place the resistance changing material layer 214 in a high resistive state, as shown by the thick band 608 in FIG. 6A. In some embodiments, the heat resulting from the current that flows through the resistance changing material layer 214 causes the resistance changing material layer 214 to change to a high resistive state.

When the resistance changing material layer 214 is in a high resistance state, as shown in FIG. 6A, the effective dielectric thickness between the substrate 202 and the control gate 212 may be higher than when he resistance changing material 214 is in a low resistance state as shown in FIG. 6C. As the effective dielectric thickness decreases, the capacitance of the gate structure may increase. The increase in capacitance of the gate structure may then decrease the threshold voltage of the memory device 200. Conversely, an increase in the resistance of the resistance changing material 214 may increase the effective dielectric thickness. An increased effective dielectric thickness may decrease the capacitance of the gate structure, which may then increase the threshold voltage of the memory device 200.

All of the methods disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. For example, one of ordinary skill in the art will recognize that silicon may be doped either by diffusion or ion implantation and that those processes may be interchanged in some situations. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

What is claimed is:

1. An apparatus comprising:
a substrate;
a source region in the substrate;
a drain region in the substrate; and
a gate structure comprising
a tunnel oxide layer on the substrate substantially between the source region and the drain region;
a floating gate layer on the tunnel oxide layer;
a resistance changing material (“RCM”) layer on the floating gate layer, wherein the RCM layer comprises a RCM; and
a control gate on the RCM layer.

2. The apparatus of claim 1, wherein the tunnel oxide layer is less than about 30 Angstroms thick.

3. The apparatus of claim 1, wherein the RCM layer is configured to alternate between a low resistance state and a high resistance state.

4. The apparatus of claim 1, wherein the RCM layer decreases the effective dielectric thickness between the substrate and the control gate when the RCM layer is in a low resistance state.

5. The apparatus of claim 1, wherein the RCM layer increases the effective dielectric thickness between the substrate and the control gate when the RCM layer is in a high resistance state.

6. The apparatus of claim 1, wherein the effective dielectric thickness between the substrate and the control gate determines a memory state of the apparatus.

7. The apparatus of claim 1, wherein the RCM layer decreases the capacitance of the gate structure when the RCM layer is in a high resistance state.

8. The apparatus of claim 1, wherein the RCM layer increases the capacitance of the gate structure when the RCM layer is in a low resistance state.

9. The apparatus of claim 1, wherein the RCM layer decreases the threshold voltage of the apparatus when the RCM layer is in a low resistance state.

10. The apparatus of claim 1, wherein the RCM layer increases the threshold voltage of the apparatus when the RCM layer is in a high resistance state.

11. An Integrated Circuit (IC) device, comprising:
a chip package configured to house an IC;
a plurality of electrical interface pins coupled to the chip package and in communication with the IC, the electrical interface pins configured to conduct electrical signals; and
an IC comprising at least one memory device disposed within the chip package comprising:
a substrate;
a source region in the substrate;
a drain region in the substrate;
a tunnel oxide layer on the substrate substantially between the source region and the drain region;
a floating gate layer on the tunnel oxide layer;
a RCM layer on the floating gate layer, wherein the resistance changing layer comprises a RCM; and
a control gate on the RCM layer.

12. The IC of claim 11, wherein the resistance of the RCM layer of at least one memory device determines the memory state of the memory device.

13. A method for fabricating a transistor comprising:
providing a substrate;
forming a source region in the substrate;
forming a drain region in the substrate;
forming a tunnel oxide layer on the substrate substantially between the source region and the drain region;
forming a floating gate layer on the tunnel oxide layer;
forming a RCM layer on the floating gate layer; and
forming a control gate on the RCM layer.

14. The method of claim 13, wherein forming the tunnel oxide layer on the substrate between the source region and the drain region comprises depositing less than about 30 Angstroms of silicon oxide on the substrate.

15. The method of claim 13, wherein forming the floating gate layer comprises depositing between 5-50 nm of polycrystalline silicon.

16. The method of claim 13, wherein forming the RCM layer on the tunnel oxide comprises depositing between 3-30 nm of RCM.

17. The method of claim 13, wherein forming the RCM layer comprises depositing two or more RCMs.

18. A method comprising:
applying a voltage across a control gate and a substrate;
changing a resistance of a RCM layer in response to the voltage;
modifying an effective dielectric thickness between the substrate and the gate in response to the resistance of the RCM layer;
modifying a capacitance of the gate structure in response to the effective dielectric thickness; and
removing the voltage without changing the resistance to substantially the value before applying the voltage

19. The method of claim 18, wherein changing the resistance of the RCM layer in response to the voltage comprises increasing the resistance.

20. The method of claim 18, wherein changing the resistance of the RCM layer in response to the voltage comprises decreasing the resistance.
